(19) United States
(12) Patent Application Publication
(10) Pub. No.: US 2009/0051023 A1
(43) Pub. Date: Feb. 26, 2009

(54) STACK PACKAGE AND METHOD OF FABRICATING THE SAME

(75) Inventors: Tae-Duk NAM, Chungcheongnam-do (KR); Hee-Jin PARK, Chungcheongnam-do (KR); Jeong-Joon OH, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/969,727

(22) Filed: Jan. 4, 2008

(30) Foreign Application Priority Data
Jan. 5, 2007 (KR) 2007-0001689

(51) Int. Cl. H01L 23/02

(52) U.S. Cl. 257/686; 257/E23.01

(57) ABSTRACT

Provided is a stack package comprising: a substrate comprising a cavity; a first semiconductor chip disposed in the cavity; and a second semiconductor chip stacked on the substrate and electrically connected to the substrate by a plurality of conductive external terminals such as conductive bumps. Since both a horizontal packaging method using bonding wires and a flip-chip packaging method are used and the bonding wires of the horizontal package and the conductive external terminals for the flip-chip bonding are formed on substantially the same plane, the total height of the stack package is reduced.

### CROSS-REFERENCE TO RELATED PATENT APPLICATION

This application claims priority under 35 USC § 119 to Korean Patent Application No. 10-2007-0001689, filed on Jan. 5, 2007 in the Korean Intellectual Property Office, the contents of which are incorporated herein in their entirety by reference.

### BACKGROUND

1. Technical Field

The present invention relates to a semiconductor package, and more particularly, to a stack package in which a plurality of semiconductor chips are stacked.

2. Description of the Related Art

With the recent development of smaller and higher performance electrical and electronic devices, higher capacity semiconductor modules are required. One solution to meet the demand for higher capacity semiconductor modules is to use semiconductor packaging technology to increase the capacity of individual semiconductor packages. Accordingly, multi-chip package (MCP) technology, which mounts a plurality of chips in a single package, has recently been developed. MCPs feature high capacity, high performance, and small size by vertically stacking a plurality of chips, having the same function or different functions, in a single package. Package in package (PIP) technology, which stacks a plurality of packages in a single package, has also been developed.

Semiconductor packages can generally be divided into a wire bonding type and a flip-chip bonding type according to the semiconductor chip interconnection method used in the package. Wire bonding connects an external connection electrode of a semiconductor chip to a connection terminal of a substrate using conductive wires. Flip-chip bonding connects a semiconductor chip to a connection terminal of a substrate using conductive bumps disposed on an external connection electrode of the semiconductor chip. Such semiconductor chip interconnection methods are used to connect packages as well.

One technique for reducing the size of a semiconductor package is called a horizontal package in which a semiconductor chip is disposed in a cavity formed in the package substrate so that that the semiconductor chip can be on the same level as the package substrate. In the horizontal package, the semiconductor chip is connected to the package substrate by wire bonding. Since the semiconductor chip is disposed on the same level as the package substrate, the height of the horizontal package is less than that of a package in which a semiconductor is disposed on a package substrate. However, since the semiconductor chip is connected to the package substrate by wire bonding, a molding process must be performed to protect the wires, thereby increasing the height of the horizontal package and leading to a complex manufacturing process.

Meanwhile, as semiconductor chips have recently been highly integrated into a small area to achieve high performance, considerable heat is generated during operation. The heat generated in the semiconductor chips significantly increases the temperature of the package, thereby increasing the risk of malfunction. To solve this problem, various attempts have been made to dissipate the heat generated in the semiconductor chips.

### SUMMARY

The present invention provides a stack package whose height can be reduced and which can be easily fabricated. The present invention also provides a method of fabricating a stack package whose height can be reduced and which can be easily fabricated. The present invention further provides a stack package which can provide high heat dissipation efficiency, can be manufactured with a reduced height, and can be simply fabricated, and a method of fabricating the stack package.

According to an aspect of the present invention, there is provided a stack package comprising: a substrate comprising a cavity; a first semiconductor chip disposed in the cavity; and a second semiconductor chip stacked on the substrate by flip-chip bonding.

### BRIEF DESCRIPTION OF THE DRAWINGS

The above and other features and advantages of the present invention will become more apparent by describing in detail exemplary embodiments thereof with reference to the attached drawings in which:

FIGS. 1A through 1C are cross-sectional views illustrating a method of fabricating a stack package according to an embodiment of the present invention; and

FIGS. 2A through 2C are cross-sectional views illustrating a method of fabricating a stack package according to another embodiment of the present invention.

### DETAILED DESCRIPTION

The present invention will now be described more fully with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. Like reference numerals refer to like elements throughout.

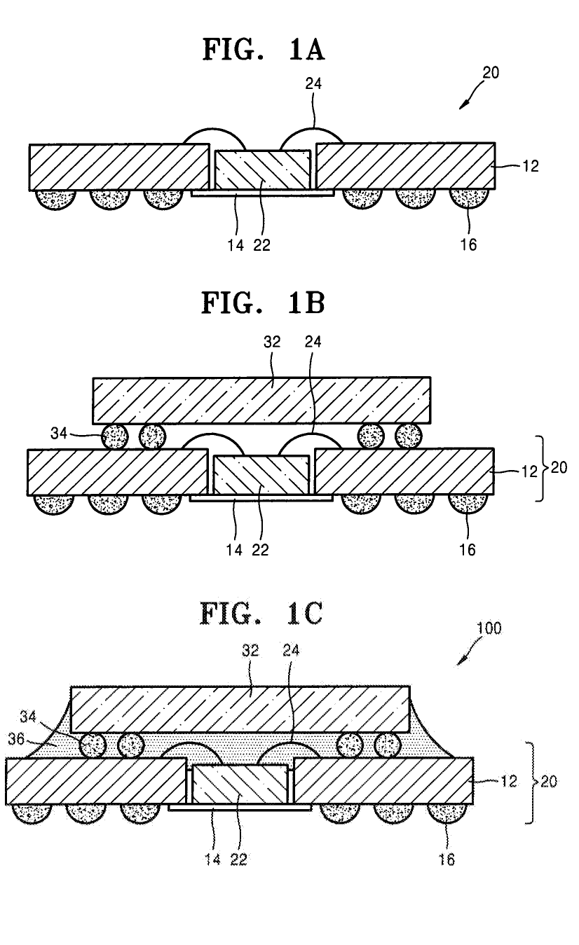

FIGS. 1A through 1C are cross-sectional views illustrating a method of fabricating a stack package 100 according to an embodiment of the present invention. The structure of the stack package 100 will now be explained first with reference to FIG. 1C.

Referring to FIG. 1C, the stack package 100 includes a horizontal package 20 including a first semiconductor chip 22, and a second semiconductor chip 32 flip-chip bonded onto the horizontal package 20.

The horizontal package 20 includes a substrate 12, and the first semiconductor chip 22 is disposed in a cavity formed in the substrate 12. The first semiconductor chip 22 is electrically connected to the substrate 12 by bonding wires 24. Since the first semiconductor chip 22 is disposed in the substrate 12 and the first semiconductor chip 22 is lower in height than the substrate 12, the height of the horizontal package 20 is defined by the sum of the height of the substrate 12 and the height of the bonding wires 24. The first semiconductor chip 22 is adhered to and supported on a support tape 14 that is connected to a bottom surface of the substrate 12.

The second semiconductor chip 32 is flip-chip bonded onto the horizontal package 20 by conductive external terminals such as conductive bumps 34. In the present embodiment, the conductive bumps 34 of the second semiconductor chip 32 are formed outside the bonding wires 24 of the horizontal package 20. Since the conductive bumps 34 and the bonding wires 24 are disposed on substantially the same plane, the total height of the stack package 100 can be reduced.

An underfill resin 36 is filled between the horizontal package 20 and the second semiconductor chip 32. Without the help of a molding material surrounding the package, the bonding wires 24 of the horizontal package 20 can be protected and the second semiconductor chip 32 can be completely flip-chip bonded to the horizontal package 20 using only the underfill resin 36. Here, the underfill resin 36 may comprise a low viscosity liquid epoxy material and a filler material such as silica.

As described above, the stack package 100 according to the present embodiment employs both a horizontal packaging method using the bonding wires 24 and a flip-chip packaging method. Accordingly, the stack package 100 has a package on package (POP) structure. Since the bonding wires 24 and the conductive bumps 34 are formed on substantially the same plane, only the taller one of the height of the bonding wires 24 and the height of the conductive bumps 34 affects the total height of the stack package 100. Therefore, the stack package 100 can be made thin. Since a separate molding material is not used and only the underfill resin 36 is used during the flip-chip bonding, the total height of the stack package 100 can be reduced further.

A method of fabricating the stack package 100 according to an embodiment of the present invention will now be explained with reference to FIGS. 1A through 1C. Referring to FIG. 1A, the first semiconductor chip 22 is fixed in the cavity formed in the substrate 12 and is connected to the substrate 12 by the bonding wires 24 to form the horizontal package 20. The first semiconductor chip 22 is adhered onto the support tape 14 that is connected to the bottom surface of the substrate 12, such that the first semiconductor chip 22 can be fixed to the substrate 12. Since the height of the first semiconductor chip 22 is lower than the height of the substrate 12, the height of the horizontal package 20 is defined by the sum of the height of the substrate 12 and the height of the bonding wires 24.

Referring to FIG. 1B, the second semiconductor chip 32 is flip-chip bonded onto the horizontal package 20. That is, the second semiconductor chip 32 is electrically connected to and stacked on the horizontal package 20 by connecting the conductive bumps 34 formed on a bottom surface of the second semiconductor chip 32 to the horizontal package 20. The conductive bumps 34 connect an external connection electrode (not shown) of the second semiconductor chip 32 to a connection pad (not shown) of the horizontal package 20.

Referring to FIG. 1C, the underfill resin 36 is filled between the horizontal package 20 and the second semiconductor chip 32. As described above, the underfill resin 36 may comprise a low viscosity liquid epoxy material and a filler material such as silica. Since the bonding wires 24 of the horizontal package 20 are covered by the underfill resin 36, a separate molding material for the horizontal package 20 is not required, thereby reducing the total height of the stack package 100 and simplifying the fabricating process of the stack package 100.

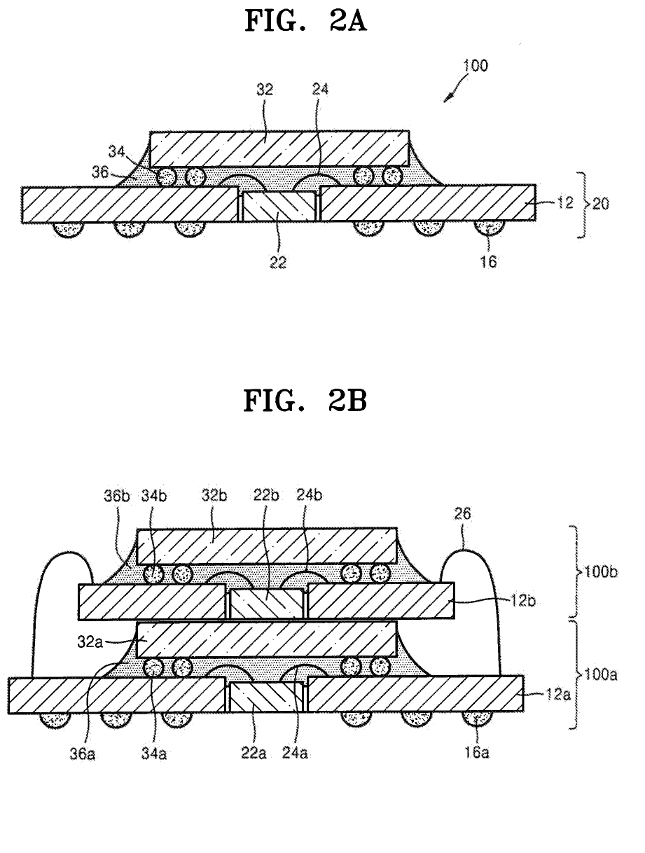

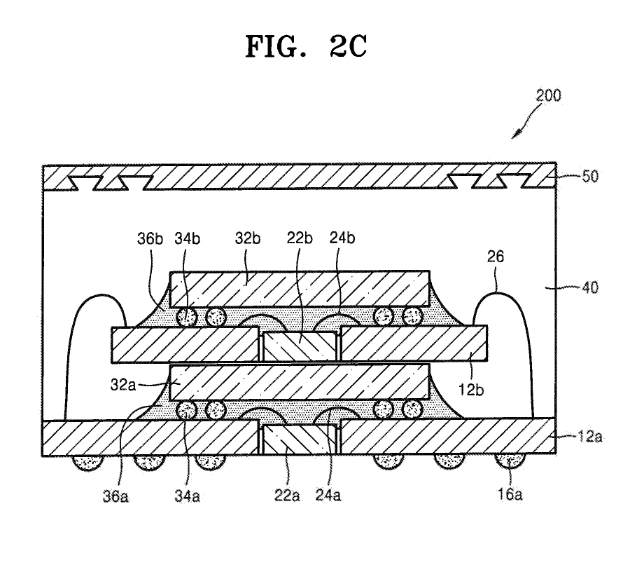

FIGS. 2A through 2C are cross-sectional views illustrating a method of fabricating a stack package 200 according to another embodiment of the present invention. In FIGS. 2B and 2C, suffix ‘a’ is added to reference numerals of elements of a lower package 100a, and suffix ‘b’ is added to reference numerals of elements of an upper package 100b. The same reference numerals as those in FIGS. 1A through 1C indicate the same elements.

The structure of the stack package 200 will now be explained first with reference to FIG. 2C. Referring to FIG. 2C, the stack package 200 includes two stack packages 100a and 100b each constructed as described in FIGS. 1A through 1C. The upper package 100b is electrically connected to the lower package 100a by bonding wires 26, and the multi-stack package 200 is protected by a molding material 40. Conductive bumps 16a that can be connected to an external substrate are formed on a bottom surface of a substrate 12a of the lower package 100a. While the upper package 100b is wire-bonded to the lower package 100a, the present embodiment is not limited thereto, and thus conductive bumps may be formed on the upper package 100b and the upper package 100b may be flip-chip bonded to the lower package 100a. A heat spreader 50 is formed on the molding material 40 to efficiently dissipate heat generated in the stack package 200.

A method of fabricating the stack package 200 according to an embodiment of the present invention will now be explained with reference to FIGS. 2A through 2C. Referring to FIG. 2A, unit stack packages 100 are formed as described above with reference to FIGS. 1A through 1C. Referring to FIG. 2B, the unit stack packages 100a and 100b are stacked, and the upper package 100b is electrically connected to the lower package 100a by the bonding wires 26. Referring to FIG. 2C, the resulting stacked structure of FIG. 2B is molded with the molding material 40. During the molding process, the heat spreader 50 is attached to a heat-resistant tape (not shown) and then attached to the molding material 40. After the molding process, the heat-resistant tape is removed such that only the heat spreader 50 is left on a top surface of the molding material 40. At this time, the heat spreader 50 may be clamped to the molding material 40 by serrated grooves formed in the heat spreader 50. Since the heat spreader 50 is formed simultaneously with the molding process, the total height of the stack package 200 can be reduced and the fabricating process of the stack package can be simplified.

According to an aspect of the present invention, there is provided a stack package comprising: a substrate comprising a cavity; a first semiconductor chip disposed in the cavity; and a second semiconductor chip stacked on the substrate by flip-chip bonding.

The first semiconductor chip and the substrate may be electrically connected to each other by bonding wires.

The stack package may further comprise an underfill resin filled between the second semiconductor chip and the substrate comprising the first semiconductor chip. The underfill resin may substantially surround the bonding wires.

The first semiconductor chip may have a height lower than the height of the substrate. The first semiconductor chip may be adhered to and supported on a support tape that is connected to a bottom surface of the substrate.

The bottom surface of the substrate may further comprise an external connection electrode. Conductive bumps may be formed on the external connection electrode.

According to another aspect of the present invention, there is provided a method of forming a stack package, the method comprising: forming a horizontal package by fixing a first semiconductor chip in a cavity formed in a substrate and wire-bonding the first semiconductor chip to the substrate using bonding wires; flip-chip bonding a second semiconductor chip onto the horizontal package; and filling an underfill resin between the second semiconductor chip and the horizontal package to substantially surround the bonding wires of the horizontal package.

The first semiconductor chip may have a height lower than the height of the substrate. The first semiconductor chip may be adhered to and supported on a support tape that is connected to a bottom surface of the substrate.

The bottom surface of the substrate may further comprise an external connection electrode. Conductive bumps may be formed on the external connection electrode.

According to another aspect of the present invention, there is provided a stack package comprising a plurality of unit stack packages stacked on one another, wherein each of the unit stack packages comprises: a horizontal package comprising a substrate and a first semiconductor chip that is disposed in a cavity formed in the substrate and is wire-bonded to the substrate using bonding wires; a second semiconductor chip flip-chip bonded onto the horizontal package; and an underfill resin filled between the horizontal package and the second semiconductor chip. The stack package may further comprise a molding material protecting the unit stack packages. The stack package may further comprise a heat spreader disposed on a top surface of the molding material. The heat spreader may be clamped to the molding material by serrated grooves formed in the heat spreader.

According to another aspect of the present invention, there is provided a method of fabricating a stack package, the method comprising: stacking a plurality of unit stack packages; molding the stacked unit stack packages with a molding material by attaching a heat-resistant tape to which a heat spreader is attached to a top surface of a molding material and compressing both the heat spreader and the molding material; and removing the heat-resistant tape from the heat spreader attached to the top surface of the molding material.

The unit stack packages may be electrically connected to one another by wire bonding. The unit stack packages may be electrically connected by flip-chip bonding.

As described above, since both the horizontal packaging method using the bonding wires and the flip-chip packaging method are used and the bonding wires of the horizontal package and the conductive bumps for the flip-chip bonding are formed on substantially the same plane, the total height of the stack package according to the present invention can be reduced. Also, since a plurality of stack packages can be stacked as a single stack package and, in this case, the heat spreader is formed simultaneously with the molding process of the stack package, the total height of the stack package according to the present invention can be further reduced and the fabricating process of the stack package can be simplified.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A stack package comprising:
a substrate comprising a cavity;
a first semiconductor chip disposed in the cavity; and
a second semiconductor chip stacked on the substrate and electrically connected to the substrate by a plurality of conductive external terminals.

2. The stack package of claim 1, wherein the first semiconductor chip and the substrate are electrically connected to each other by bonding wires.

3. The stack package of claim 1, further comprising an underfill resin disposed between the second semiconductor chip and the substrate comprising the first semiconductor chip.

4. The stack package of claim 3, wherein the underfill resin substantially surrounds the bonding wires.

5. The stack package of claim 1, wherein the first semiconductor chip has a height lower than a height of the substrate.

6. The stack package of claim 1, wherein the first semiconductor chip is adhered to and supported on a support tape that is connected to a bottom surface of the substrate.

7. The stack package of claim 1, wherein a bottom surface of the substrate further comprises an external connection electrode.

8. The stack package of claim 7, wherein the conductive external terminals are formed on the external connection electrode.

9. A stack package, comprising:
a plurality of unit stack packages stacked on one another, wherein each of the unit stack packages comprises:
a horizontal package comprising a substrate and a first semiconductor chip that is disposed in a cavity in the substrate and is wire-bonded to the substrate using bonding wires;
a second semiconductor chip stacked on the horizontal package and electrically connected to the substrate by a plurality of conductive external terminals; and
an underfill resin disposed between the horizontal package and the second semiconductor chip.

10. The stack package of claim 9, further comprising a molding material disposed around the unit stack packages.

11. The stack package of claim 10, further comprising a heat spreader disposed on a top surface of the molding material.

12. The stack package of claim 11, wherein the heat spreader is clamped to the molding material by serrated grooves formed in the heat spreader.
